(19) United States
(12) Patent Application Publication
(10) Pub. No.: US 2026/0044657 A1
(43) Pub. Date: Feb. 12, 2026

(54) OPTIMIZATION TOOL WITH DYNAMIC, SCALABLE ACQUISITION FUNCTION

(71) Applicant: INTERNATIONAL BUSINESS MACHINES CORPORATION, Armonk, NY (US)

(72) Inventors: Robert PERRICONE, New City, NY (US); Bria MATTHEWS, Austin, TX (US); David Wells WINSTON, Asheville, NC (US); Tong LI, Austin, TX (US)

(21) Appl. No.: 18/796,592

(22) Filed: Aug. 7, 2024

(51) Int. Cl. G06F 30/337

(52) U.S. Cl. CPC G06F 30/337

(57) ABSTRACT

A multi-state acquisition function engine is provided for enhancing operation of an optimization tool to optimize a circuit device feature. Running the acquisition function engine facilitates tailoring optimization samples for objective function evaluation. The process includes configuring input parameters for running a genetic algorithm engine based, in part, on a current acquisition function state to tune the genetic algorithm engine based on the state. Further, the process includes running the genetic algorithm engine for one or more generations using the configured input parameters to generate a plurality of candidate samples, and providing selected sample(s) of the plurality of candidate samples to the objective function for generating a respective fitness score for optimizing the circuit design feature. The process further includes selecting, based at least in part on the generated fitness score(s), a new acquisition function state of the acquisition function engine for a next iteration.

### BACKGROUND

The present invention relates to design and manufacture of circuit devices, such as integrated circuits (ICs), integrated circuit chips, etc., and more particularly, to very large-scale integration (VSLI) designs and devices based on analysis and optimization of such circuit devices using an optimization tool, such as a Bayesian optimization tool.

Bayesian optimization is a machine learning tool that can be used to navigate large and complex search spaces to optimize, for instance, a circuit device feature, such as a circuit design, logic module design, device design, etc. For example, Bayesian optimization can be used to optimize circuit sizing, multi-scale circuit designs, thermal designs, etc. A Bayesian optimization tool uses a surrogate model as a proxy for the true objective function that estimates the function values at points that have not yet been evaluated. The surrogate model is designed to capture the uncertainty in the function's behavior and quantify the uncertainty of its predictions. In addition, a Bayesian optimization tool includes an acquisition function that is built using the surrogate model, and which samples the surrogate function to find candidate samples for objective function evaluation.

The majority of acquisition functions are intractable, or are only tractable in a handful of special cases. To circumvent the lack of closed-form solutions, a number of diverse methods have been proposed including approximation strategies (e.g., entropy search) to replace a quantity of interest with a more readily computable one, which work well but may not converge to a true value, bespoke solutions that provide near-analytic expressions, but typically do not scale well with dimensionality, and Monte Carlo (MC) methods that are versatile and generally unbiased, but are often perceived as non-differentiable and, therefore, inefficient for the purpose of maximizing an acquisition function.

### SUMMARY

Certain shortcomings of the prior art are overcome, and additional advantages are provided herein through the provision of a computer-implemented method of enhancing processing within a computing environment. The computer-implemented method includes running, as part of an optimization tool, a state iteration of an acquisition function including a multi-state acquisition function engine, where the optimization tool is a machine learning optimization tool to optimize, at least in part, a circuit device feature, and the multi-state acquisition function engine facilitates selecting samples for objective function evaluation. The multi-state acquisition function engine has multiple potential acquisition function states ranging from an exploitive state to an explorative state. The method further includes configuring input parameters for running a genetic algorithm engine of the optimization tool based, in part, on a current acquisition function state of the multiple potential acquisition function states of the multi-state acquisition function engine to tune the genetic algorithm engine based on the current acquisition function state. The method further includes running the genetic algorithm engine for one or more generations using the configured input parameters to generate a plurality of candidate samples for the objective function, and providing one or more selected samples of the plurality of candidate samples to the objective function for generating one or more fitness scores for the selected sample(s) in optimizing, at least in part, the circuit device feature. Further, the method includes selecting, based in part on the generated fitness score(s) for the selected sample(s), a new acquisition function state of the multi-state acquisition function engine of the acquisition function for a next iteration.

Computer program products and computer systems relating to one or more aspects are also described and claimed herein. Further, services relating to one or more aspects are also described and may be claimed herein.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1A depicts one example of a computing environment to include and/or use one or more of the aspects of the present disclosure;

FIG. 1B depicts another example of a computing environment to include and/or use one or more aspects of the present disclosure;

FIG. 2 depicts one embodiment of a computer program product with an optimization tool, in accordance with one or more aspects of the present disclosure;

FIG. 3 depicts one embodiment of an optimization tool process, in accordance with one or more aspects of the present disclosure;

FIG. 4A depicts an overview embodiment of an optimization tool process, in accordance with one or more aspects of the present disclosure;

FIG. 4B depicts a graphical example of a Bayesian optimization tool process, in accordance with one or more aspects of the present disclosure;

FIG. 5 depicts one embodiment of an acquisition function module workflow;

FIG. 6A depicts a further embodiment of an optimization tool workflow, in accordance with one or more aspects of the present disclosure;

FIG. 6B illustrates one embodiment of multiple potential acquisition function states of a multi-state acquisition function engine of a dynamic, scalable acquisition function, such as the dynamic, scalable acquisition function of FIG. 6A, in accordance with one or more aspects of present disclosure;

FIG. 6C depicts one embodiment of a pre-processing weighting of genetic algorithm input parameters based on a current acquisition function state, in accordance with one or more aspects of the present disclosure;

FIG. 7 is a flow diagram of a design process used in semiconductor design, manufacture, and test, in which aspects of the present disclosure can be employed;

FIG. 8 depicts a further example of integrated circuit fabrication, including generating physical design data, in accordance with one or more aspects of the present disclosure; and

FIG. 9 shows an exemplary high-level Electronic Design Automation (EDA) tool flow, in which aspects of present disclosure can be employed.

### DETAILED DESCRIPTION

Aspects of the present disclosure and certain features, advantages, and details thereof, are explained more fully below with reference to the non-limiting example(s) illustrated in the accompanying drawings. Descriptions of well-known systems, devices, processing techniques, etc., are omitted so as not to unnecessarily obscure the disclosure in detail. It should be understood, however, that the detailed description and the specific example(s), while indicating aspects of the disclosure, are given by way of illustration only, and are not by way of limitation. Various substitutions, modifications, additions, and/or arrangements, within the spirit and/or scope of the underlying inventive concepts will be apparent to those skilled in the art for this disclosure. Note further that reference is made below to the drawings, where the same or similar reference numbers used throughout different figures designate the same or similar components. Also, note that numerous inventive aspects and features are disclosed herein, and unless otherwise inconsistent, each disclosed aspect or feature is combinable with any other disclosed aspect or feature as desired for a particular application of the concepts disclosed.

Note also that illustrative embodiments are described below using specific code, designs, architectures, protocols, layouts, schematics, systems, or tools only as examples, and not by way of limitation. Furthermore, the illustrative embodiments are described in certain instances using particular software, hardware, tools, and/or data processing environments only as example for clarity of description. The illustrative embodiments can be used in conjunction with other comparable or similarly purposed structures, systems, applications, architectures, etc. One or more aspects of an illustrative control embodiment can be implemented in software, hardware, or a combination thereof.

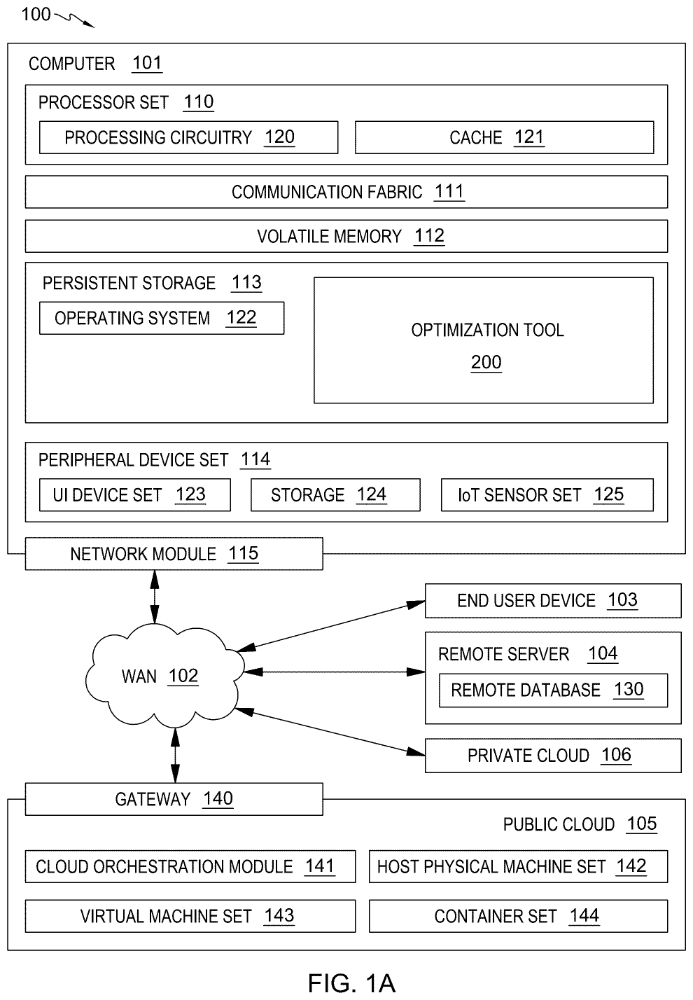

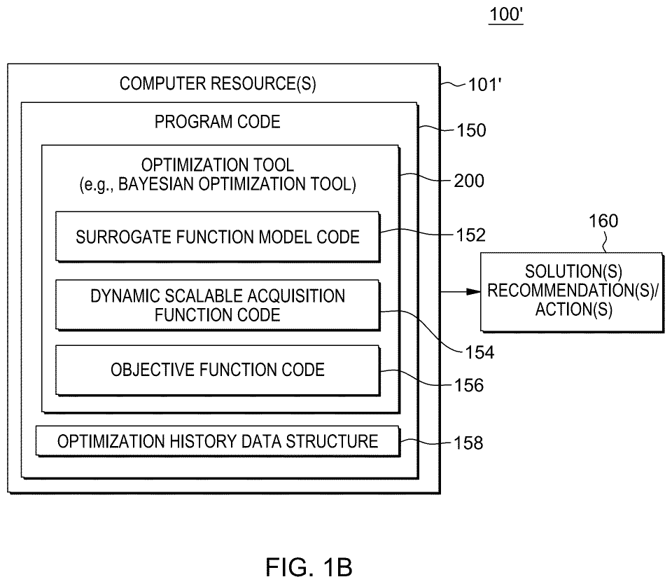

As understood by one skilled in the art, program code, as referred to in this application, can include software and/or hardware. For example, program code in certain embodiments of the present disclosure can utilize a software-based implementation of the functions described, while other embodiments can include fixed function hardware. Certain embodiments combine both types of program code. Examples of program code, also referred to as one or more programs, are depicted in FIG. 1, including operating system 122 and optimization tool 200, which are stored in persistent storage 113.

One or more aspects of the present disclosure are incorporated in, performed and/or used by a computing environment. As examples, the computing environment can be of various architectures and of various types, including, but not limited to: personal computing, client-server, distributed, virtual, emulated, partitioned, non-partitioned, cloud-based, quantum, grid, time-sharing, clustered, peer-to-peer, mobile, having one node or multiple nodes, having one or more processor sets, each with one processor or multiple processors, and/or any other type of environment and/or configuration, etc., that is capable of executing a process (or multiple processes) that, e.g., perform capacitance extraction-related processing, such as disclosed herein. Aspects of the present disclosure are not limited to a particular architecture or environment.

Prior to further describing detailed embodiments of the present disclosure, examples of computing environments to include and/or use one or more aspects of the present disclosure are discussed below with reference to FIGS. 1A-1B.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

As illustrated in FIG. 1A, computing environment 100 contains an example of an environment for the execution of at least some of the computer code involved in performing the inventive methods, such as optimization tool or block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Cloud computing services and/or microservices (not separately shown in FIG. 1A): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

The computing environment described above is only one example of a computing environment to incorporate, perform and/or use one or more aspects of the present disclosure. Other examples are possible. Further, in one or more embodiments, one or more of the components/modules of FIG. 1A need not be included in the computing environment and/or are not used for one or more aspects of the present disclosure. Further, in one or more embodiments, additional and/or other components/modules can be used. Other variations are possible.

By way of further example, FIG. 1B depicts another embodiment of a computing environment 100′, which can incorporate, or implement, one or more aspects of an embodiment of the present disclosure. In one or more embodiments, computing environment 100′ is implemented as part of, or includes, a computing environment such as computing environment 100 described above in connection with FIG. 1A. Computing environment 100′ contains one or more computing resources 101′, such as one or more computers 101 of FIG. 1A, that execute program code 150 that implements, for instance, one or more aspects of optimization tool 200, such as disclosed herein. In one or more embodiments, optimization tool 200 is a machine learning optimization tool, such as a Bayesian optimization tool, which includes, in one embodiment, surrogate function model code 152, dynamic, scalable acquisition function code 154, and objective function code 156. In one embodiment, optimization tool 200 further includes an optimization history data structure 158 which stores, or includes, samples (or points) input to objective function code 156, as well as the resultant fitness scores for those samples.

In one or more embodiments, optimization tool 200 is configured to optimize, for instance, a circuit device feature, such as an aspect or component of an integrated circuit, integrated circuit chip, electronic device, printed circuit board, etc. including, for instance, a circuit design, such as circuit size, design of multi-scale circuits, thermal design, etc. In one or more embodiments, optimization tool 200 provides the optimized circuit device feature as part of one or more solutions/recommendations/actions 160 to facilitate, for instance, fabrication of the circuit device (e.g., integrated circuit, integrated circuit chip, electronic device, print circuit board, etc.). In one or more implementations, computing environment 100′ can include, or utilize, one or more networks for interfacing various aspects of computing resource(s) 101′, as well as one of or more other components, systems, etc., receiving an output, solution, action, etc. 160 of the optimization tool to facilitate performance of one or more design and fabrication operations. By way of example, the network(s) can be, for instance, a telecommunications network, a local area network (LAN), a wide area network (WAN), such as the Internet, or a combination thereof, and can include wired, wireless, fiber optic connections, etc. The network(s) can include one or more wired and/or wireless networks that are capable of receiving and transmitting data, including training data for one or more machine learning models of the optimization tool, and an output solution, recommendation, action of the machine learning optimization tool, such discussed herein.

In one or more implementations, computing resource(s) 101′ house and/or execute program code 150 configured to perform computer-implemented methods in accordance with one or more aspects of the present disclosure. By way of example, computing resource(s) 101′ can be a computing-system-implemented resource(s). Further, for illustrative purposes only, computing resource(s) 101′ in FIG. 1B is depicted as being a single computing resource. This is a non-limiting example of an implementation. In one or more other embodiments, computing resource(s) 101′, which implements one or more aspects of processing such as discussed herein, can, at least in part, be implemented in multiple separate computing resources or systems, such as one or more computing resources of a cloud-hosting environment, by way of example.

Briefly described, in one embodiment, computing resource(s) 101′ can include one or more processor sets with one or more processors, for instance, central processing units (CPUs). Also, the processor set(s) can include functional components used in the integration of program code, such as functional components to fetch program code from locations in memory, such as cache or main memory, decode program code, and execute program code, access memory for instruction execution, and write results of the executed instructions or code. The processor set(s) can also include a register(s) to be used by one or more of the functional components. In one or more embodiments, the computing resource(s) can include memory, input/output, a network interface, and storage, which can include and/or access, one or more other computing resources and/or databases, as required to implement the optimization tool processing described herein. The components of the respective computing resource(s) can be coupled to each other via one or more buses and/or other connections. Bus connections can be one or more of any of several types of bus structures, including a memory bus or a memory controller, a peripheral bus, an accelerated graphics port, and a processor or local bus, using any of a variety of architectures. By way of example, but not limitation, such architectures can include the Industry Standard Architecture (ISA), the micro-channel architecture (MCA), the enhanced ISA (EISA), the Video Electronic Standard Association (VESA), local bus, and peripheral component interconnect (PCI). As noted, examples of a computing resource(s), or computing system(s) or competitor(s), which can implement one or more aspects disclosed are described further herein with reference to the figures.

In one or more embodiments, program code 150 includes, or executes, one or more artificial intelligence agents which train and use one or more machine learning models that embody or are used by the machine learning optimization tool 200. The models can be trained using training data that can include a variety of types of data points. In one or more embodiments, program code 150 executing on one or more computing resources 101′ applies one or more algorithms of, for instance, the artificial intelligence agent(s) to generate and train the model(s), which the program code then utilizes to, for instance, implement one or more aspects of optimization tool 200. In an initialization or learning stage, program code 150 trains one or more machine learning models using obtained training data to implement, for instance, one or more aspects of the code, functions and/or modules described herein.

Data used to train the models (in one or more embodiments of the present disclosure) can include a variety of types of data, such as data generated by one or more data sources for the optimization process and/or data stored in one or more databases accessible by, the computing resource(s). Program code, in embodiments of the present disclosure, can perform data analysis to generate data structures, including algorithms utilized by the program code to implement the optimization tool and/or initiate (or perform) an action. As known, machine learning-based modeling solves problems that cannot be solved by numerical means alone. In one example, program code extracts features/attributes from the training data, which can be stored in memory or one or more databases. The extracted features can be utilized to develop a predictor function, h(x), also referred to as a hypothesis, which the program code utilizes as a model. In identifying machine learning model(s), various techniques can be used to select features (elements, patterns, attributes, etc.), including but not limited to, diffusion mapping, principal component analysis, recursive feature elimination (a brute force approach to selecting features), and/or a random forest, to select the attributes related to the particular model. Program code can utilize one or more algorithms to train the model(s) (e.g., the algorithms utilized by program code), including providing weights for conclusions, so that the program code can train any predictor or performance functions included in the model. The conclusions can be evaluated by a quality metric. By selecting a diverse set of training data, the program code trains the model to identify and weigh various attributes (e.g., features, patterns) that correlate to enhanced performance of the model.

In one or more embodiments, program code, executing on one or more processors, utilizes an existing cognitive analysis tool or agent (now known or later developed) to tune the model, based on data obtained from one or more data sources. In one or more embodiments, the program code can interface with application programming interfaces to perform a cognitive analysis of obtained data. Specifically, in one or more embodiments, certain application programing interfaces include a cognitive agent (e.g., learning agent) that includes one or more programs, including, but not limited to, natural language classifiers, a retrieve-and-rank service that can surface the most relevant information, concepts/visual insights, tradeoff analytics, document conversion, and/or relationship extraction. In an embodiment, one or more programs analyze the data obtained by the program code from one or more sources utilizing one or more of a natural language classifier, retrieve-and-rank application programming interfaces, and tradeoff analytics application programing interfaces, etc.

In one or more embodiments, the program code can utilize one or more neural networks (NNs) to analyze training data and/or collected data to generate an operational machine learning model. Neural networks are a programming paradigm which enable a computer to learn from observational data. This learning is referred to as deep learning, which is a set of techniques for learning in neural networks. Neural networks, including modular neural networks, are capable of pattern (e.g., state) recognition with speed, accuracy, and efficiency, in situations where datasets are mutual and expansive, including across a distributed network, including but not limited to, cloud computing systems. Modern neural networks are non-linear statistical data modeling tools. They are usually used to model complex relationships between inputs and outputs, or to identify patterns (e.g., states) in data (i.e., neural networks are non-linear statistical data modeling or decision-making tools). In general, program code utilizing neural networks can model complex relationships between inputs and outputs and identified patterns in data. Because of the speed and efficiency of neural networks, especially when parsing multiple complex datasets, neural networks and deep learning provide solutions to many problems in multi-source processing, which program code, in embodiments of the present disclosure, can utilize in implementing a machine learning model, such as described herein.

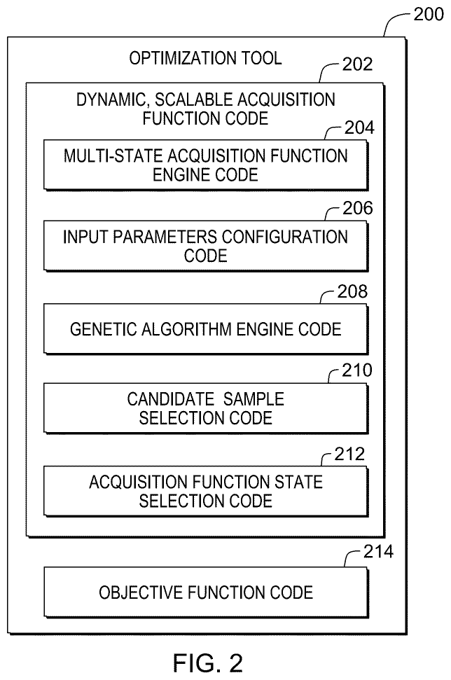

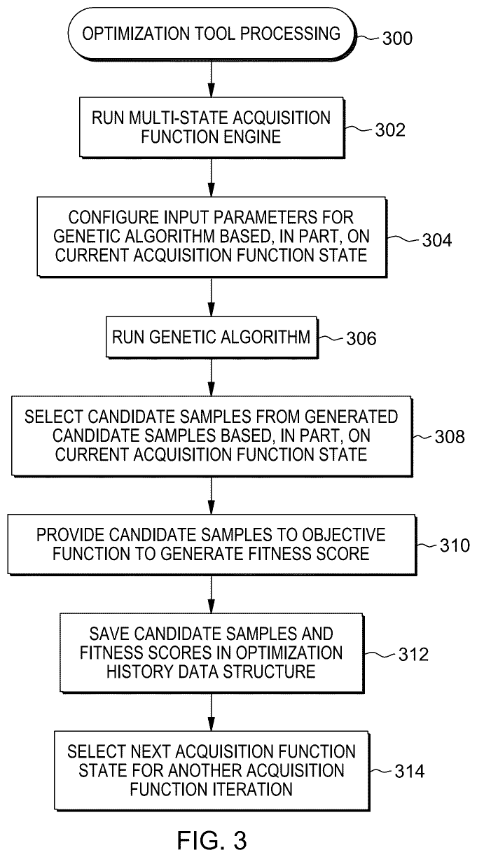

By way of example, one or more embodiments of an optimization tool and process are described initially with reference to FIGS. 2-3. FIG. 2 depicts one embodiment of an optimization tool or module 200 that includes code or instructions to perform machine learning optimization processing, in accordance with one or more aspects of the present disclosure, and FIG. 3 depicts one embodiment of an optimization tool process, in accordance with one or more aspects of the present disclosure.

Referring to FIGS. 1A-2, optimization tool 200 includes, in one example, various code or sub-modules used to perform processing, in accordance with one or more aspects of the present disclosure. The sub-modules are, e.g., computer-readable program code (e.g., instructions) in computer-readable media (e.g., persistent storage (e.g., persistent storage 113, such as a disk) and/or a cache (e.g., cache 121), as examples). The computer-readable media can be part of a computer program product and can be executed by and/or using one or more computers, such as computer(s) 101; one or more processor sets 110 (FIG. 1A); processors, such as one or more processors of processor set 110; and/or processing circuitry, such as processing circuity of processor set 110, etc.

As noted, FIG. 2 depicts one embodiment of optimization tool 200 which, in one or more implementations, includes, or facilitates, Bayesian optimization processing in accordance with one or more aspects of the present disclosure. In the embodiment of FIG. 2, example code of optimization tool 200 include dynamic, scalable acquisition function code 202, which includes multi-state acquisition function engine code 204 to run, as part of optimization tool 200, state iterations, where the machine learning optimization tool is to optimize, at least in part, a circuit device feature, and the multi-state acquisition function engine tailors, and facilitates selecting, optimization samples for objective function evaluation. The multi-state acquisition function engine has multiple potential acquisition function states ranging from an exploitive state to an explorative state. In addition, dynamic, scalable acquisition function code 202 includes input parameters configuration code 206 to configure input parameters for running a genetic algorithm engine of the optimization tool based, in part, on a current acquisition function state of the multi-state acquisition function engine to tune the genetic algorithm engine based on the current acquisition function state. Further, dynamic, scalable acquisition function code 202 includes genetic algorithm engine code 208 to run the genetic algorithm engine for one or more generations using the configured input parameters to generate a plurality of candidate samples (or points, parameters, etc.) for the objective function evaluation. In addition, in one or more embodiments, dynamic, scalable acquisition function code 202 includes sample selection code 210 to, for instance, apply data analysis to the plurality of the candidate samples to select, based at least in part on the current acquisition function state, samples for the objective function from the plurality of candidate samples. In one or more embodiments, dynamic, scalable acquisition function code 202 further includes acquisition function state selection code 212, and optimization tool 200 further includes objective function code 214. Objective function code 214 generates one or more fitness scores for one or more selected samples in optimizing, at least in part, the circuit device feature, and acquisition function state selection code 212 selects, based at least in part on the generated fitness score(s) for the selected sample(s), a new acquisition function state of the multi-state acquisition function engine for a next state iteration of the acquisition function. Note that in this regard that the acquisition function state for the next iteration of the process steps noted can be the same acquisition function state or a different acquisition function state than the prior acquisition function state.

Note also that although various code or sub-modules are described herein, optimization tool processing, such as disclosed, can use, or include, additional, fewer, and/or different code/sub-modules. A particular code can include additional code, including code of other sub-modules, or less code. Further, additional and/or fewer code/sub-modules can be used. Many variations are possible.

Advantageously, in one or more aspects disclosed herein, processing within a computing environment is improved by facilitating, for instance, design and manufacture of circuit devices, such as integrated circuits, specifically, by facilitating very large-scale integration (VLSI) designs and devices based on analysis (and optimization) of one or more circuit device features. The circuit device features can be any feature, attribute, component, etc. to be optimized, for a circuit, circuit design, chip device, circuit board, package, system, etc.

Disclosed herein, in one or more embodiments, is an enhanced optimization tool which includes a dynamic, scalable acquisition function code that facilitates quickly finding viable and/or optimal samples for objective function evaluation. The dynamic, scalable acquisition function code dynamically balances exploitation versus exploration for high dimensional spaces on a performance basis, and includes a multi-state acquisition function engine with multiple potential acquisition function states ranging from an exploitive state to an explorative state. Advantageously, experimental analysis indicates significant performance improvement in optimizing various circuit device features. Optimal and/or viable designs are obtained earlier in the process than conventional approaches, and the dynamic, scalable acquisition function code disclosed herein ensures that potential optimal locations are well exploited. For instance, in one or more tests, the dynamic, scalable acquisition function disclosed herein performs 90% less simulations then traditional approaches, identifies a globally optimal design 85% faster than traditional approaches, and also utilizes fewer computing resources, such as fewer grid machine resources, than other approaches. As discussed herein, a circuit design optimization example is one use only of the optimization tool disclosed, and other uses will be apparent to those skilled in the art, including optimization of a variety circuit features, chip features, board features, machine features, system features, etc. (collectively referred to herein as circuit device features).

In one or more embodiments, the optimization tool is used, in accordance with one or more aspects of the present disclosure, to perform Bayesian optimization processing. FIG. 3 depicts one example of optimization tool processing 300, such as disclosed herein. The process is executed, in one or more embodiments, by a computer (e.g., computer 101 (FIG. 1)), and/or one or more processor sets, such as a processor or processing circuitry (e.g., of processor set 110 of FIG. 1). In one example, code or instructions implementing the process, are part of a code or module, such as optimization tool 200 of FIGS. 1A-2. In other examples, the code can be included in one or more other modules and/or one or more other sub-modules of one or more other modules. Various options are available.

As illustrated in FIG. 3, in one example, optimization tool processing 300 executing on one or more computers (e.g., computer 101 of FIG. 1A), one or more processor sets (e.g., processor set 110 of FIG. 1A, such as a processor or processing circuitry of the processor set) performs optimization of a circuit device feature processing such as described herein, which includes, in one or more embodiments, running a state iteration of the multi-state acquisition function engine 302. The optimization tool is a machine learning optimization tool to optimize, at least in part, the circuit device feature, and the multi-state acquisition function engine facilitates selecting samples for an objective function of the optimization tool, where the multi-state acquisition function has multiple potential acquisition function states ranging from an exploitive state to an explorative state. Optimization tool processing 300 further includes configuring input parameters for the genetic algorithm engine based, in part, on the current acquisition function state of the multiple potential acquisition function states of the multi-state acquisition function engine to tune the genetic algorithm engine based on the current acquisition function state 304. Optimization tool processing also includes running the generic algorithm engine for one or more generations using the configured input parameters to generate a plurality of candidate samples for the objection function 306. In addition to the preprocessing of input parameters for the genetic algorithm engine, based on the current state, optimization tool processing 300 further includes post processing the generated plurality of candidate samples for the objective function to select candidate samples based, in part, on the current acquisition function state using data analysis 308. In one or more embodiments, optimization tool processing 300 further includes providing one or more selected samples to the objective function to generate one or more fitness scores 310 and saving the selected samples and fitness scores in an optimization history data structure 312 for reference, for instance, in configuring the input parameters for the genetic algorithm engine for subsequent acquisition function states. In one or more embodiments, optimization tool processing 300 further includes selecting, based at least in part on the generated fitness scores for the selected samples, a new acquisition function state of the multi-state acquisition function for a next state iteration of the acquisition function and above-noted process 314. The selected acquisition function state can be the same state or a different state then the prior acquisition function state iteration depending, for instance, on the candidate samples and the fitness score(s).

As noted, Bayesian optimization is a machine learning tool that can be used to navigate large and complex search spaces to optimize, for instance, a circuit device feature, such as circuit design, logic module design, device design, etc. For example, Bayesian optimization can be used for circuit sizing, multi-scale circuit designs, thermal design optimizations, etc. A Bayesian optimization tool uses a surrogate function model as a proxy for the true objective function that estimates the function values at points that have not yet been evaluated. The surrogate model, such as a Gaussian Process Regression (GPR), is designed to capture the uncertainty in the function's behavior and quantify the uncertainty of its predictions.

The Bayesian optimization tool further includes an acquisition function to sample the surrogate function for optimal points or samples for objective function evaluation. The objective function computes the fitness score (i.e., the result of the objective function evaluation) of the received optimal points or samples. This process continues to loop and incorporate newly computed training data until the optimization saturates or other imposed limits are encountered. A disadvantage of Bayesian optimization is that its runtime scales cubically with the size of the input design data. For example, Bayesian optimization is inefficient for large feature spaces of, for instance, 20 or more parameters. This is true, in part, because the majority of acquisition functions are intractable, or are only tractable in a handful of special cases. In a properly formatted Bayesian optimization, any bottleneck in processing should be the objective function itself, and not the acquisition function. To address this issue, a scalable, dynamic acquisition function is disclosed herein that includes a meta-heuristic approach to enabling the scalable acquisition function.

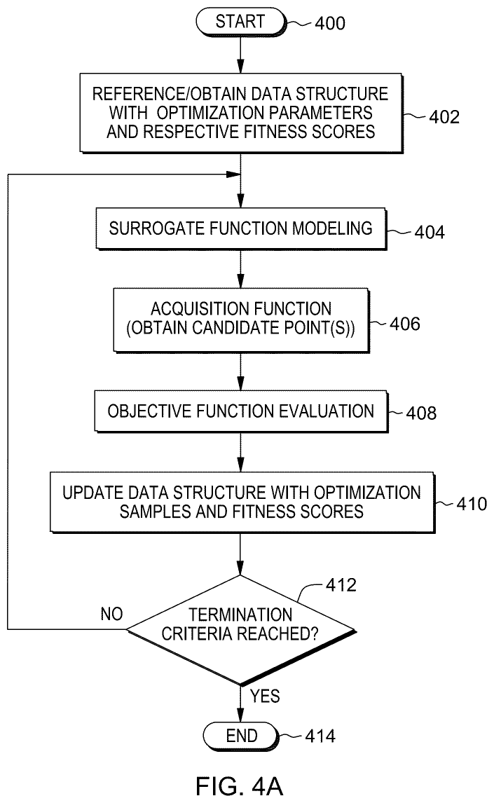

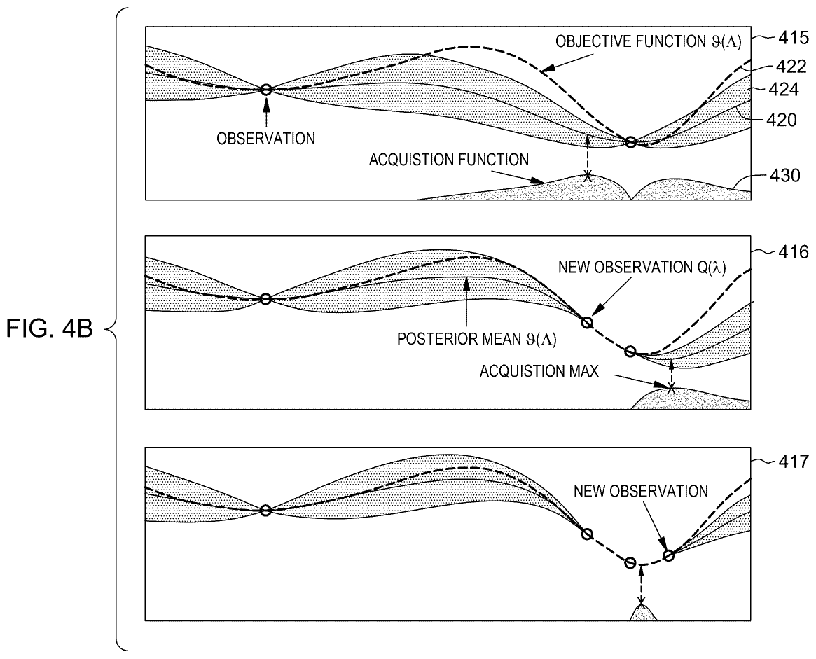

By way of example, FIG. 4A depicts an overview embodiment of an optimization tool process, which can be used in accordance with one or more aspects of present disclosure, and FIG. 4B depicts an example Bayesian optimization using a process such as depicted, for instance, in FIG. 4A.

As illustrated in FIG. 4A, the process starts 400 with initiating building, data structure with optimization parameters (or samples) and respective fitness scores 402. Fitness scores represent objective function evaluations for each sample or point. Surrogate function modeling is performed 404 along with running an acquisition function to obtain candidate samples (or candidate points) 406. By way of example, surrogate function modeling can be performed through Gaussian Process Regression (GPR) with a radial basis function kernel. Conventionally, acquisition function sampling can be performing through a variety of classical optimization algorithms, such as the Broyden-Fletcher-Goldfarb-Shanno (BFGS) algorithm. In operation, a metric, such as an Expected Improvement, is used to determine best candidate samples or points, in one embodiment. One or more candidate samples can be evaluated by the objective function to determine optimality. The candidate samples are fed to an objective function for evaluation 408, and the evaluated optimization samples and fitness scores are used to update the data structure 410.

Note that the objective function is a function to optimize (e.g., obtain a maximum or minimum) a specified feature, such as a circuit device feature, as described herein. Inputs to the objective function are the optimization samples (or parameters, points, etc.) and the output is the fitness score for the optimization samples relative to the goal of optimizing the particular feature. The process continues until a termination criteria 412 is reached, which ends the process 414. The termination criteria can be, for instance, to run the optimization tool for a specified number of iterations without encountering a specified better fitness score. In example graph 415 of FIG. 4B, surrogate function model output 420 has an uncertainty 424 about the output given there are only two observation points on the object function 422 so far. An acquisition function 430 is run to select a next sample or point to be used in objective function evaluation, as illustrated in example graph 416. Again a maximum acquisition sample is identified (in this example), as illustrated, which once evaluated provides a new observation point along the objective function further refining the optimization, as illustrated the example graph 417 of FIG. 4B. Note in this regard that the acquisition function has its own heuristic to determine which next point would be the best to send to the objective function for evaluation.

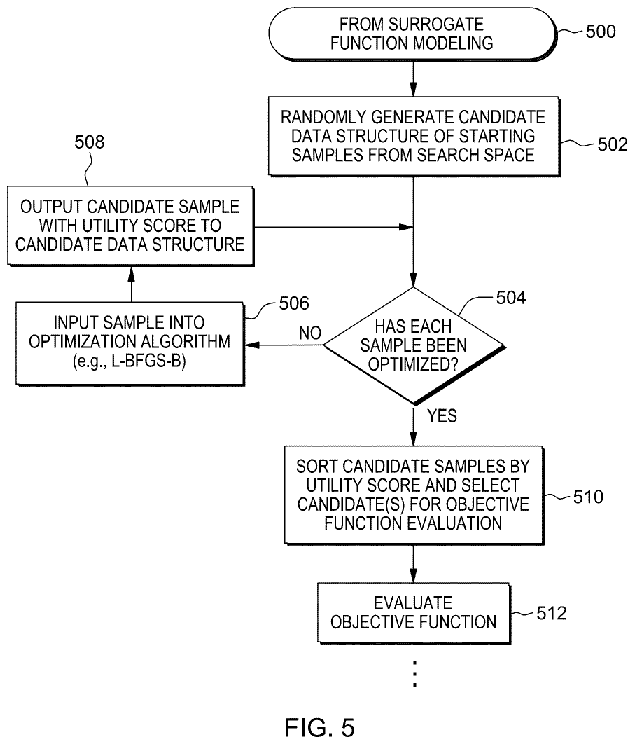

FIG. 5 illustrates one embodiment of an acquisition function code workflow. In one or more embodiments, the surrogate function modeling 500 is used to randomly generate a data structure with starting candidate samples from a search space 502. The acquisition function samples the surrogate function to find candidates for the objective function evaluation. An aspect of the acquisition function is to balance exploration versus exploitation (to avoid local extreme traps), and can be considered its own optimization problem. For instance, it can be desirable to optimize a metric such as an upper confidence bound (UCB) for the input surrogate function and sample points. The computed score is referred to as the utility score, and the output is a list of samples sorted by utility score (depending on the desired minimum or maximum goal). As illustrated in FIG. 5, processing determines whether each sample has been optimized 504, and if “no”, then a sample is input to an optimization algorithm, such as a L-BFGS-B algorithm, which is a limited memory algorithm for serving large non-linear optimization problems subject to simple bounds on the variables 506. It is in the family of quasi-Newton methods that approximate the Broyden-Fletcher-Goldfarb-Shanno algorithm. The optimization algorithm outputs processed samples with scores to the candidate data structure 508. The process continues until each sample has been optimized, after which the samples are sorted by the scores and candidates are selected for the objective function evaluation 510, with objective function evaluation 512 following selection of the samples.

As noted, the majority of acquisition functions currently available are intractable, or are only tractable in a handful of special cases. To circumvent the lack of closed-form solutions, a number of diverse methods have been proposed including approximation strategies (e.g., entropy search) to replace a quantity of interest with a more readily computable one, which work well but may not converge to a true value, bespoke solutions (e.g., Expected Improvement (EI) design) that provide near-analytic expressions, but typically do not scale well with dimensionality, and Monte Carlo (MC) methods that are versatile and generally unbiased, but often are perceived as non-differentiable and, therefore, inefficient for the purpose of maximizing an acquisition function.

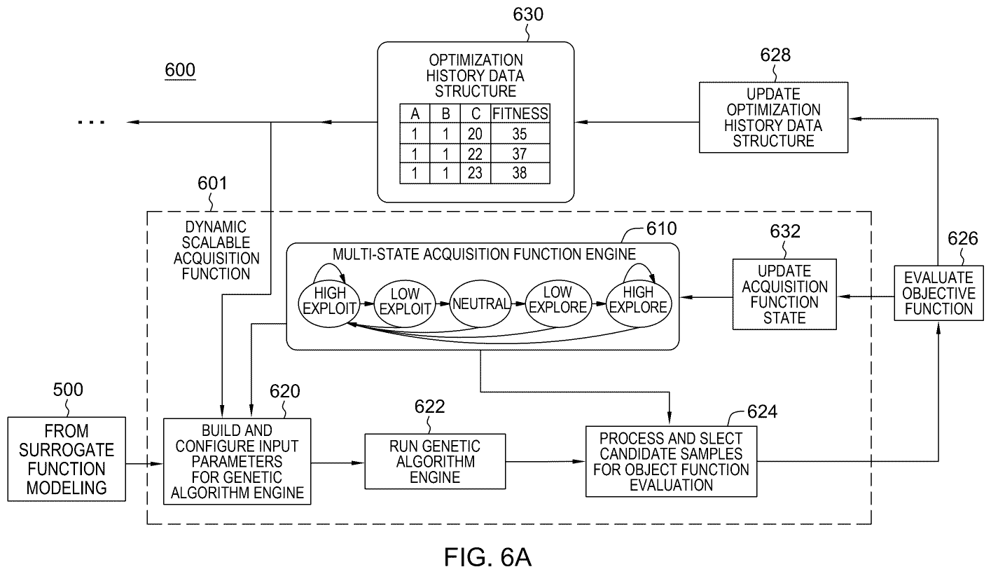

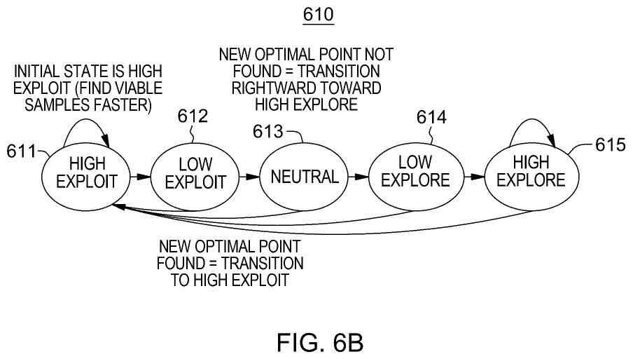

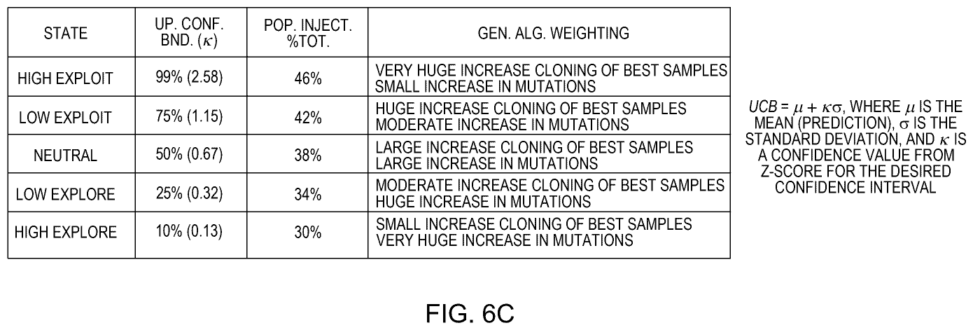

FIG. 6A depicts a further embodiment of an optimization tool process 600, in accordance with one or more aspects of the present disclosure. Optimization tool process 600 includes, in part, a dynamic, scalable acquisition function 601 which samples the surrogate function 500 to find candidate samples for objective function evaluation. In the embodiment illustrated, dynamic, scalable acquisition function 601 includes a multi-state acquisition function engine 610 that has multiple potential acquisition function states 611-615, as illustrated in the partially enlarged view of FIG. 6B. In particular, as illustrated in FIG. 6B, the multiple potential acquisition function states include a high exploit state 611 and a high explore state 615 with, in one or more embodiments, one or more states between the exploit and explore states. In the first state example of FIGS. 6A & 6B, this includes a low exploit state 612, a neutral state 613, and a low explore state 614. Note that this is one example only, and that in other examples there can be any desired number of potential acquisition function states between high exploit state 611 and high explore state 615.

As disclosed herein, dynamic, scalable acquisition function 601 utilizes a dynamic meta-heuristic, implemented by multi-state acquisition function engine 610, to facilitate scaling to larger feature spaces. The meta-heuristic configures the genetic algorithm based on the performance of the optimization process, and there is a balance between exploitation and exploration. As illustrated in FIG. 6B, in one or more embodiments, the initial state of the multi-state acquisition function engine 610 is the high exploit state 611 to facilitate finding viable samples faster. In one or more embodiments, from one state iteration to the next, if there is no optimal point found in the prior state iteration, then there is a transition rightward in the direction of the high explore state 615. For instance, in one or more embodiments, from high exploit state 611, if there is no optimal point found in the prior state iteration, then the multi-state acquisition function engine transitions to the low exploit state 612, etc. From each state, if there is a new optimal point found in that state iteration, then the next state returns to the high exploit state 611 to explore the new optimal point or sample. Thus, there is a balance between exploitation and exploration based on performance of the optimizer. Each state has parameters based on different areas that influence the performance and operation of the acquisition function. For instance, in one or more embodiments, each acquisition function state includes respective parameters that: weigh genetic algorithm operations that affect mutations, cloning, etc.; select an initial candidate population to prime the genetic algorithm's search; set the acquisition function's utility metric to be more exploitive or explorative; sort the plurality of candidate samples; and facilitate selecting candidate samples for the objective function evaluation.

Collectively, the state-based meta-heuristic disclosed herein embodies a fast, scalable acquisition function that balances exploitation verses exploration based on the optimizer's current performance. For instance, in the more exploitative state, the acquisition function can run very quickly since the search is focused near the best sets of parameters found thus far (i.e., how the initial population is set). The acquisition function utility function is set to emphasize improvements around the best sets parameters. The more the function searches in familiar spaces, the faster it converges. The inherent properties of the genetic algorithm and Bayesian learning are used in this process to complete the search within, for instance, minutes verses hours or days for more gradient-based acquisition function searches. As explained herein, there is a desire to maintain a more exploitive state in the acquisition function for the majority of the optimization process. In the more explorative state, the acquisition function runs longer than in the exploitative state. In this state, the search is focused on new spaces and sub-optimal spaces that haven't been thoroughly explored. The search performance can be balanced by setting a limit on the number of generations in the genetic algorithm. With the present disclosure, if multiple optimizations are identified, then the acquisition function is guaranteed to search each of them. Note that the neutral state 613 of the acquisition function engine is effectively a balance state between exploitation and exploration. Remaining in the neutral state, the algorithm inherently tries to balance between exploration and exploitation.

Conventionally, in large search spaces, a significant amount of time can be spent sampling the total search space. This is especially true early on when there are few known samples (that is, lack of knowledge). In the time taken to exhaustedly sample the space, several optimal extrema may have been discovered, but can not typically be exploited until the initial emphasis on exploration has complete. Within the same time frame, several optimal points could have been exploited had the algorithm been able to dynamically balance itself, as in the multi-state acquisition function engine disclosed herein. Advantageously, the multi-state acquisition function engine 610 disclosed, for instance, in FIGS. 6A & 6B, facilitates a scalable acquisition function that is capable of quickly finding viable and/or optimal samples for objective function evaluation. The engine dynamically balances exploitation verses exploration for high dimensional spaces on a performance basis.

Continuing with FIG. 6A, intelligent pre-processing and post-processing of samples based on optimization performance is performed as part of the dynamic, scalable acquisition function 601. As illustrated, the pre-processing includes building and configuring input parameters for the genetic algorithm engine 620. This pre-processing is based, in part, on the current acquisition function state of the multiple potential acquisition function states of the multi-state acquisition function engine 610 to tune the genetic algorithm engine inputs based on the current acquisition state. For instance, as illustrated in FIG. 6C, the upper confidence bound (UCB) can be equal to μ+κσ, where μ is the mean (prediction), σ is the standard deviation, and κ is a confidence value from the Z-score for the desired confidence interval. These variables or parameters are an example of three configuration parameters that can be used to set up the genetic algorithm based on the acquisition function state, which as noted, results in tuning the genetic algorithm based on the current state. By changing the confidence level scaling factor, how the algorithm balances between exploitation and exploration is modified.

With the tuned input parameters, the genetic algorithm engine is run for one or more generations to generate a plurality of candidate samples for the objective function 622. In one or more embodiments, the population sizes can be defaulted to 10× the number of optimization samples or parameters. In one or more embodiments, the genetic algorithm engine can run for 100 generations, with 25 generations being set as a stop condition if no new candidate samples are identified. In one or more embodiments, if the number of optimization samples or parameters are less than or equal to 20, then the acquisition function can operate using a simplified optimization approach. For instance, the simplified process can include randomly generating N unique samples (which are also unique from previously evaluated points in the data history table), where N is generally a large number (such as 500) depending on the number of optimization parameters and the size of the search space. The surrogate function model, randomly generated points, and acquisition function metric (UCB) are input to, for instance, a L-BFGS-B algorithm. For each randomly generated point, the score that represents the optimal UCB point is found (e.g., minimization) is output. Once all scores have been computed for each sample, a K-means clustering can be performed on the data, which uses their distances from each other for the clustering. A few cluster iterations are run until an even spread of the data is obtained (usually 3-5 clusters). Each cluster can be sorted by ascending score, and several candidates selected from each cluster. The total number of candidates selected depends on the user-input value. The number of candidates selected from each cluster varies depending upon the progress of the optimization process.

Once the genetic algorithm engine completes, post processing of the sorted candidate samples is performed to select samples for object function evaluation 624. As noted, the current state of the multi-state acquisition function engine 610 can be used to effect this data analysis process, that is, to tailor selecting from the candidate optimization samples the particular samples for the objective function. In one or more embodiments, the candidate sample list can be pruned by removing any duplicate (clone) entries. In addition, any candidate samples that already exist in the data history table can be removed. In one or more embodiments, candidate selection includes determining the samples that will be evaluated by the objective function. For instance, K-means clustering is performed on the candidate samples, with parameter sample distances being used as the clustering metric. The number of clusters depends on the acquisition function state (generally 3-5 for exploit-explore, respectively). Each cluster is sorted by utility score, with the percentage of candidates selected from each cluster varying, in one or more embodiments, depending on the acquisition function state. For instance, in a high exploit state 50% of the candidates can be selected from the cluster with the best average utility score. If a new optimal point was discovered in the previous iteration, then 50% of the candidate samples can be selected from the cluster with the lowest average utility score, and the remaining 50% of the candidates can be uniformly selected from the best points in the remaining clusters. If a new optimal point was not discovered in the previous state iteration, then the best candidates can be uniformly selected from each cluster, in one or more embodiments.

The selected samples or parameters are provided to the objective function for evaluation and generating of fitness scores for the selected samples in optimizing, the specified circuit device feature, as described herein 626. In one or more embodiments, the process further includes updating 628 the optimization history data structure 630 with the evaluated samples and generated fitness scores. Further, the process includes updating the acquisition function state 632 by selecting, based at least in part on the generated fitness scores for the selected candidate samples, an acquisition function state of the multi-state acquisition function engine for a next state iteration of the multi-state acquisition function engine 632, with the next state being selected, such as described herein from the multiple potential acquisition function states ranging from the exploitive state to the explorative state.

Those skilled in the art will note from the above description that, in one or more aspects, provided herein is a method of providing a black box optimization tool, which includes obtaining data and historical information for a high dimensional space, and generating an algorithm using a meta-heuristic approach, by using the data and historical information for the high dimensional space. Further, the method includes using the algorithm to generate a scalable acquisition function, where the scalable acquisition function provides solutions to problems having a set of variables with constraints, and a set of unknowns by balancing exploitation and exploration possibilities in the solution.

By way of further example, the optimization tool and process disclosed herein can be used to facilitate, for instance, a circuit design optimization. Conventionally, circuit design optimization is a tedious process that often relies on a designer's intuition with elements of trial and error. The design process is exacerbated by increasing circuit complexity and long simulation times. As disclosed herein, a dynamic, scalable acquisition function can be integrated within an optimization tool to better automate, for instance, the circuit design optimization process. Advantageously, the process disclosed herein reduces the time for obtaining an optimal design, inherently utilizes fewer computing resources, is scalable to higher dimensional spaces, can be implemented as a fully automated resource management system that acquires and manages remote computing resources for each simulation requested by the optimizer, only requires a user to determine the optimization parameters to be used and determine the objective function to be optimized, the optimization parameters used can be integers (including binary) or continuous, and the user can select a number of objective function operations per iteration (i.e., parallel simulations on a compute grid can be used) to further speed up the optimization. In one or more embodiments, data structure and plots can be output, to for instance, provide a visualization of the optimization flow over each iteration.

Initially, a circuit optimization workflow using the optimization tool and processes disclosed herein can include a user providing a text file that contains optimization parameters, with upper/lower bounds, and step size. The user can also specify any constraints on the optimization parameters written as Boolean expressions. The user provides a netlist file and, if necessary, a separate analysis file for simulations. The optimization parameters appear in these files. The user provides a text file that contains the objective function to be optimized (maximized or minimized). The objective function includes variables that represent measurements from their simulation output. Using a parsing syntax, the names of the objective function variables are specified, in addition to the netlist and analysis required to run in order to obtain these measurements. Note that a user is not limited to a single netlist/analysis. The optimization tool supports multiple netlists/analyses and only requires that the path be specified to their location in computer storage. In one or more embodiments, a graphical user interface can be used to specify the locations of the above-noted input items in addition to any optimization configuration settings desired. These types of options include settings such as convergence criteria, max number of iterations, number of initial training samples, number of acquisition function recommendations, and number of remote machine resources.

In one or more embodiments, the user can also indicate whether a design space exploration is to be performed, a training/validation and test, or a fully optimization is desired. For instance, a design space exploration can perform a user-specified number of objective function evaluations. The input optimization parameters for each objective function evaluation are randomly generated. Once the number of user-requested objective function evaluations is complete, the user receives output results and fitness scores for the randomly generated optimization points. This data can be used to evaluate their objective function output and ensure the setup is correct before performing a full optimization run. The data can also be used as input into a full optimization run as training data.

In one or more embodiments, the training and validation option allows a user to input previously generated training data and have it split into training, validation and testing tables. The optimization process can proceed with the surrogate function modeling, either a standard GPR or a neural network-based GPR. If the neural network-based GPR is selected, then training loss, validation loss, and R2 scores can be produced and returned to the user. Further, the testing data can be used in the root-mean-square-error (RMSE) can be computed on the predictions and their actual values. This option can be used to tune the neural network to avoid over/under-fitting.

In one or more embodiments, the full optimization option can be selected when a user is ready to perform a fully automated optimization of a design. This option can run for a specified number of iterations or until a user-defined convergence criteria occurs (e.g., number of iterations without finding a new optimal design).

With the above-noted inputs set, the optimization tool can run, with the following description assuming that a full optimization process is being performed. The optimization process begins by reading and checking the selected configuration options. This is done to avoid potential issues such as any missing files and/or missing directories. The text file that contains the optimization parameters is checked. The tool takes note of each optimization parameter and insures that the specified upper and lower bounds fall within a specified step size. From this input, the optimization parameters are scaled to integer boundaries and ranges if needed. For example, if an optimization parameter is received with upper and lower bounds of 0.5 and 1.0, with a step size of 0.1, this parameter can be scaled to 5.0 to 10.0 by dividing the bounds by the step size. This can be done to both simplify the random generation of input parameters and simplify the acquisition function's process of finding the optimal points or samples. Any optimization constraints are also read in by the system from the file and checked for correctness. These can be used to prevent generating samples and acquisition function recommendations from violating invalid conditions. The text file that contains the objective function can be read and checked for correctness. For a single netlist/analysis, a single simulation and output may be needed. However, multiple netlists/analyses can also be included to accommodate more complex designs. Once all inputs have been parsed and checked, the optimization tool determines how to proceed with a set of initial training samples. For the initial training samples, one or more of the following cases can be possible based on the input: a specific number of initial objective function evaluations (with a unique random set of initial samples to be generated based on the input value); a table of training samples is input (or referenced) with previously computed fitness scores; or a table of desired initial training samples to be evaluated in the objective function is input (or referenced).

While determining the number of initial samples to evaluate, the optimization tool also begins acquiring local and/or remote compute resources from, for instance, a compute grid cluster, in one or more embodiments. The number of local (e.g., subprocesses on the same computer) and remote compute resources can be a defined input, if desired. In one or more embodiments, these compute resources can be managed by a “cluster broker”. The broker process can be launched and waits for the additional compute resources to be scheduled by the grid. While the additional resources are coming online, the optimization tool can be preparing simulation work items needed to evaluate the objective function. Each of these work items can be input to a job queue that is kept by the cluster broker. The additional resources can atomically access the job queue and remove work items from it. The additional resources perform the work item tasks (e.g., simulation) and then return the requested work items'results back to the job broker's output queue (in one embodiment).

The main optimization process monitors the job broker's output queue and removes and saves the results. Once all work items have been completed, the main process evaluates the objective function from the results of each input vector and saves this in a data table as the fitness score. In one or more embodiments, the data table is de-scaled and saved on the local machine's run directory. With all initial training samples evaluated, the main optimization loop process begins. The first part in the Bayesian optimization flow is the surrogate function modeling, as described herein. This is done either through a traditional GPR or a neural network-based GPR. The decision on which to use can be based on the number of optimization parameters. As the traditional GPR does not scale well beyond 20 parameters, this number can be selected as a decision boundary for whether to use, for instance, the neural network-based approach. In one or more embodiments, before surrogate function modeling occurs, each parameter in the training data table is standardized (e.g., subtract mean and divide by standard deviation). This can be accomplished to facilitate the GPR process. The standardized data can then be input to the selected surrogate function modeling algorithm. The output is a surrogate function model that will be used in the acquisition phase to find optimal design points.

The acquisition function is the second part of the Bayesian optimization flow, and as noted, a dynamic, scalable acquisition function is disclosed and used herein. The acquisition function samples the surrogate function model to find one or more particular potential optimal points to send to be evaluated by the objective function based on a current acquisition function state. The sampling process can be guided by a metric, such as an Expected Improvement (EI), Probability of Improvement (PI), or Upper Confidence Bound (UCB) based on current performance of the optimization tool. The goal is to balance exploration versus exploitation of the surrogate function. Note that each query of the surrogate function yields a prediction (mean) and uncertainty (standard deviation), which are used to compute the values of these acquisition function metrics. In one or more embodiments, the UCB is minimized to find candidate points for objective function evaluation. Details of the acquisition function approach are described further herein.

Once the acquisition function has decided on a set of candidate samples or parameter vectors, the samples are placed in work items and input to the cluster broker's input queue. From there, the objective function evaluation process follows the above-outlined steps for processing jobs in the queue. Once the objective function evaluation and data saving have completed, one or more outputs and/or decisions can be provided or made by the automation tool. For instance, in one or more embodiments, an output plot of the optimization process of the fitness score verses iteration can be generated; an output plot of the correlation between each optimization parameter and fitness score can be generated; a text file containing a summary of the optimization and the best fitness score found per iteration and overall can be generated; if a new optimal point was found this iteration, a text file containing the best optimization parameters, fitness score, and simulation measurements can be written; the convergence criteria can be checked to see if the optimization process should continue; if convergence has not occurred, then the iteration limit can be checked to see if optimization processing should continue. If no stop condition has occurred, the optimization loop continues as described above. Once the optimization engine completes, the cluster broker releases its associated resources and, in one or more embodiments, attributes of the optimization tool process can be provided including, for instance, optimization time, best found fitness score, as well as one or more figures and graphical plots as desired to facilitate the circuit design process. The optimized design can then be used to fabricate the physical integrated circuit using one or more processes such as described herein.

Conventionally, in VLSI (very large-scale integration) digital design, fabricated devices can include millions of transistors implementing hundreds of storage devices, functional logic circuits, and the like. The designs are often segmented or partitioned into sub-blocks (such as cores, units, macros, subhierarchies, and the like) to make the design process more manageable. For example, the design, placement, and routing of circuits may be conducted at a high level and a sub-block level, where the high level considers the complete device including all sub-blocks (known as in-context design) and the sub-block level considers the design of a single sub-block (known as out-of-context design). While a sub-block level design can be used in multiple instances within a device, conventionally, only a single version of the design of the sub-block is produced.

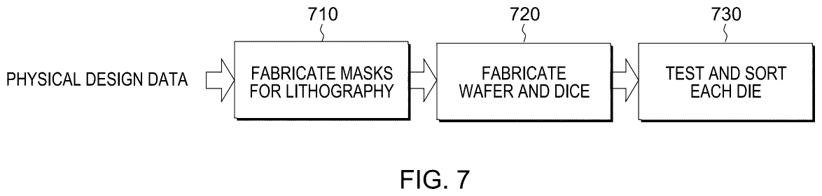

In one or more embodiments, a further step includes fabricating a physical integrated circuit in accordance with an optimized circuit device design. One non-limiting specific example that accomplishes this is described herein in connection with FIGS. 7-9. For example, a design structure, based for instance on a VLSI design, is provided to fabrication equipment to facilitate fabrication of a physical integrated circuit in accordance with the design structure.

In one or more embodiments, a layout is prepared based on the analysis. In one or more embodiments, the layout is instantiated as a design structure. In one or more embodiments, a physical integrated circuit is fabricated in accordance with the design structure.

As noted, in one or more embodiments, the layout is instantiated as a design structure. A physical integrated circuit is then fabricated in accordance with the design structure. Refer also to discussion for FIGS. 7-9. FIG. 7 is a flow diagram of a design process used in semiconductor design, manufacture, and/or test. Once the physical design data is obtained, based, in part, on the design processes described herein, an integrated circuit designed in accordance therewith can be fabricated according to known processes that are generally described with reference to FIG. 7. Generally, a wafer with multiple copies of the final design is fabricated and cut (i.e., diced) such that each die is one copy of the integrated circuit. At block 710, the processes include fabricating masks for lithography based on the finalized physical layout. At block 720, fabricating the wafer includes using the masks to perform photolithography and etching. Once the wafer is diced, testing and sorting each die is performed at 730 to filter out any faulty die. Furthermore, referring to FIGS. 7-9, in one or more embodiments, the at least one processor is operative to generate a design structure for the integrated circuit design in accordance with the VLSI design, and in at least some embodiments, the at least one processor is further operative to control integrated circuit manufacturing equipment to fabricate a physical integrated circuit in accordance with the design structure. Thus, the layout can be instantiated as a design structure, and the design structure can be provided to fabrication equipment to facilitate fabrication of a physical integrated circuit in accordance with the design structure. The physical integrated circuit will be improved (for example, because of proper signal electromigration mitigation) compared to circuits designed using prior art techniques, at least under conditions where there is the same CPU time budget for the design process. To achieve similar improvements with prior-art techniques, even if possible, would require expenditure of more CPU time as compared to embodiments of the invention.

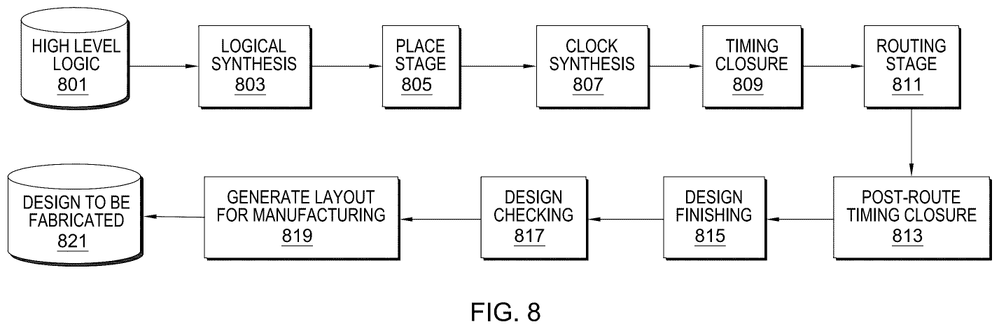

FIG. 8 depicts an example high-level Electronic Design Automation (EDA) tool flow, which is responsible for creating an optimized microprocessor (or other IC) design to be manufactured. A designer can start with a high-level logic description 801 of the circuit (e.g. VHDL or Verilog). The logic synthesis tool 803 compiles the logic and optimizes it without any sense of its physical representation, and with estimated timing information. Placement tool 805 takes the logical description and places each component, looking to minimize congestion in each area of the design. The clock synthesis tool 807 optimizes the clock tree network by cloning/balancing/buffering the latches or registers. The timing closure step 809 performs a number of optimizations on the design, including buffering, wire tuning, and circuit repowering; its goal is to produce a design which is routable, without timing violations, and without excess power consumption. Routing stage 811 takes the placed/optimized design and determines how to create wires to connect the components, without causing manufacturing violations. Post-route timing closure 813 performs another set of optimizations to resolve any violations that are remaining after the routing. Design finishing 815 then adds extra metal shapes to the netlist, to conform with manufacturing requirements. Checking steps 817 analyze whether the design is violating any requirements such as manufacturing, timing, power, electromigration or noise. When the design is clean, the final step 819 is to generate a layout for the design, representing all the shapes to be fabricated in the design to be fabricated 821.

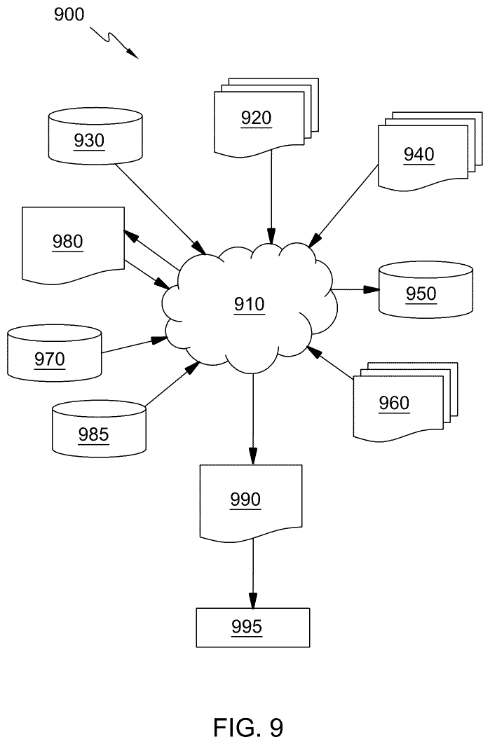

One or more embodiments integrate the timing and signal electromigration analysis techniques herein with semiconductor integrated circuit design simulation, test, layout, and/or manufacture. In this regard, FIG. 9 shows a block diagram of an exemplary design flow 900 used for example, in semiconductor IC logic design, simulation, test, layout, and manufacture. Design flow 900 includes processes, machines and/or mechanisms for processing design structures or devices to generate logically or otherwise functionally equivalent representations of design structures and/or devices, such as those that can be analyzed using timing analysis or the like. The design structures processed and/or generated by design flow 900 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., E-V writers), computers, or equipment for simulating design structures, any apparatus used in the manufacturing or test process, or any machines for programming functionality equivalent representations of the design structures into any medium (e.g., a machine for programming a programmable gate array).

Design flow 900 may vary depending on the type of representation being designed. For example, a design flow 900 for building an application specific IC (ASIC) may differ from a design flow 900 for designing a standard component or from a design flow 900 for instantiating the design into a programmable array, for example a programmable gate array (PGA) or a field programmable gate array (FPGA).

FIG. 9 illustrates multiple such design structures 920 that is preferably processed by a design process 910. Design structure 920 may be a logical simulation design structure generated and processed by design process 910 to product a logically equivalent functional representation of a hardware device. Design structure 920 may also or alternatively comprise data and/or program instructions that when processed by design process 910, generate a functional representation of the physical structure of a hardware device. Whether representing functional and/or structural design features, design structure 920 may be generated using electronic computer-aided design (ECAD), such as implemented by a core developer/designer. When encoded on a gate array or storage medium, design structure 920 may be accessed and processed by one or more hardware and/or software modules within design process 910 to simulate or otherwise functionally represent an electronic component, circuit, electronic or logic module, apparatus, device, or system. As such, design structure 920 may comprise files or other data structures including human and/or machine-readable source code, compiled structures, and computer executable code structure that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages, such as Verilog and VHDL, and/or higher level design languages, such as C or C++.

Design process 910 preferably employs and incorporates hardware and/or software modules for synthesizing, translating, or otherwise processing a design/simulation functional equivalent of components, circuits, devices, or logic structures to generate a Netlist 980, which may contain design structures such as design structure 920. Netlist 980 may comprise, for example, compiled or otherwise processed data structures representing a list of wires, discrete components, logic gates, control circuits, I/O devices, modules, etc., that describes the connections to other elements and circuits in an integrated circuit design. Netlist 980 may be recorded on a machine-readable data storage medium or programmed into a programmable gate array, a compact flash, or other flash memory. Additionally, or in the alternative, the medium may be a system or cache memory, buffer space, or other suitable memory.

Design process 910 may include hardware and software modules for processing a variety of input data structure system, including Netlist 980. Such data structure types may reside, for example, within library elements 930 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 940, characterization data 950, verification data 960, design rules 970, and test data files 985, which may include input test patterns, output test results, and other testing information. Design process 910 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 910 without deviating from the scope and spirit of the invention. Design process 910 may also include modules for performing standard circuit design processes such as timing analysis, verification, design rule checking, place and route operations, etc. Improved placement can be performed as described herein.

Design process 910 employs and incorporates logic and physical design tools such as HDL compilers and simulation model build tools to process design structure 920 together with some or all of the depicted supporting data structures along with any additional mechanical design or data (if applicable), to generate a second design structure 990. Design structure 990 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 920, design structure 990 preferably comprises one or 10 more files, data structures, or other computer-encoded data or instructions that reside on data storage media and that when processed by an ECAD system generate a logically or otherwise functionally equivalent form of one or more IC designs or the like. In one embodiment, design structure 990 may comprise a compiled, executable HDL simulation model that functionally simulates the devices to be analyzed.

Design structure 990 may also employ a data format used for the exchange of layout data of integrated circuits. and/or symbolic data format (e.g. information stored in a GDSII (GDS2), GLl, OASIS, map files, or any other suitable format for storing such design data structures). Design structure 990 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g.,. lib files). Design structure 990 may then proceed to a stage 995 where, for example, design structure 990: proceeds to tape-out, is released to manufacturing, is released to a mask house, is sent to another design house, is sent back to the customer, etc.

The terminology used herein is for the purpose of describing particular embodiments only and is not intended to be limiting of the disclosure. As used herein, the singular forms “a”, “and” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A computer-implemented method of enhancing processing within a computing environment, the computer-implemented method comprising:
running, as part of an optimization tool, a state iteration of an acquisition function including a multi-state acquisition function engine, the optimization tool being a machine learning optimization tool to optimize, at least in part, a circuit device feature, and the multi-state acquisition function engine facilitating selecting samples for an objective function of the optimization tool, the multi-state acquisition function engine having multiple potential acquisition function states ranging from an exploitive state to an explorative state;
configuring input parameters for running a genetic algorithm engine of the optimization tool based, in part, on a current acquisition function state of the multiple potential acquisition function states of the multi-state acquisition function engine to tune the genetic algorithm engine based on the current acquisition function state;
running the genetic algorithm engine for one or more generations using the configured input parameters to generate a plurality of candidate samples for the objective function;
providing one or more selected samples of the plurality of candidate samples to the objective function for generating one or more fitness scores for the selected sample(s) in optimizing, at least in part, the circuit device feature; and
selecting, based at least in part on the generated fitness score(s) for the selected sample(s), a new acquisition function state of the multi-state acquisition function engine of the acquisition function for a next iteration.

2. The computer-implemented method of claim 1, further comprising data analyzing the plurality of candidate samples to select, based at least in part on the current acquisition function state, the selected sample(s) for evaluation by the objective function from the plurality of candidate samples.

3. The computer-implemented method of claim 2, wherein the data analyzing comprises K-means clustering of the plurality of candidate samples, and identifying a percentage of candidate samples to be selected, based on the current acquisition function state, for a resultant cluster for inclusion in the selected candidate samples.

4. The computer-implemented method of claim 1, wherein the multi-state acquisition function engine is a dynamic meta-heuristic engine which facilitates, in part, configuring the input parameters for running the genetic algorithm engine based on a current performance of the optimization tool.

5. The computer-implemented method of claim 1, wherein running, as part of the optimization tool, the multi-state acquisition function engine further comprises initiating running of the multi-state acquisition function engine in the exploitive state with starting execution of the optimization tool to optimize, at least in part, the circuit device feature.

6. The computer-implemented method of claim 1, wherein selecting the new acquisition function state comprises selecting the exploitive state as the acquisition function state where the generated fitness score(s) indicates a new optimum over one or more other fitness scores generated from one or more other iterations of the acquisition function.

7. The computer-implemented method of claim 1, wherein selecting the new acquisition function state comprises selecting a more explorative state as the acquisition function state where the generated fitness score(s) indicates absence of a new optimum over one or more other fitness scores generated from one or more other iterations of the acquisition function.

8. The computer-implemented method of claim 1, wherein each acquisition function state of the multiple acquisition function states includes respective parameters that: weigh genetic algorithm operations that affect mutations and cloning, select an initial candidate population to prime the genetic algorithm's search, set the acquisition function's utility metric to be more exploitive or explorative, sort the plurality of candidate samples and facilitate selecting the selected sample(s) for the objective function.

9. The computer-implemented method of claim 1, wherein the multiple potential acquisition function states of the multi-state acquisition function engine include the exploitive state, a less exploitive state, a neutral state, a less explorative state and the explorative state.

10. A computer program product for enhancing processing within a computing environment, the computer program product comprising:
a set of one or more computer-readable storage media; and
program instructions, collectively stored in the set of one or more storage media, for causing at least one processor set to perform computer operations comprising:
running, as part of an optimization tool, a state iteration of an acquisition function including a multi-state acquisition function engine, the optimization tool being a machine learning optimization tool to optimize, at least in part, a circuit device feature, and the multi-state acquisition function engine facilitating selecting samples for an objective function of the optimization tool, the multi-state acquisition function engine having multiple potential acquisition function states ranging from an exploitive state to an explorative state;
configuring input parameters for running a genetic algorithm engine of the optimization tool based, in part, on a current acquisition function state of the multiple potential acquisition function states of the multi-state acquisition function engine to tune the genetic algorithm engine based on the current acquisition function state;
running the genetic algorithm engine for one or more generations using the configured input parameters to generate a plurality of candidate samples for the objective function;
providing one or more selected samples of the plurality of candidate samples to the objective function for generating one or more fitness scores for the selected sample(s) in optimizing, at least in part, the circuit device feature; and
selecting, based at least in part on the generated fitness score(s) for the selected sample(s), a new acquisition function state of the multi-state acquisition function engine of the acquisition function for a next iteration.

11. The computer program product of claim 10, wherein the computer operations further comprise data analyzing the plurality of candidate samples to select, based at least in part on the current acquisition function state, the selected sample(s) for evaluation by the objective function from the plurality of candidate samples.

12. The computer program product of claim 11, wherein the data analyzing comprises K-means clustering of the plurality of candidate samples, and identifying a percentage of candidate samples to be selected, based on the current acquisition function state, for a resultant cluster for inclusion in the selected candidate samples.

13. The computer program product of claim 10, wherein the multi-state acquisition function engine is a dynamic meta-heuristic engine which facilitates, in part, configuring the input parameters for running the genetic algorithm engine based on a current performance of the optimization tool.

14. The computer program product of claim 10, wherein running, as part of the optimization tool, the multi-state acquisition function engine further comprises initiating running of the multi-state acquisition function engine in the exploitive state with starting execution of the optimization tool to optimize, at least in part, the circuit device feature.

15. The computer program product of claim 10, wherein selecting the new acquisition function state comprises selecting the exploitive state as the acquisition function state where the generated fitness score(s) indicates a new optimum over one or more other fitness scores generated from one or more other iterations of the acquisition function.

16. The computer program product of claim 10, wherein selecting the new acquisition function state comprises selecting a more explorative state as the acquisition function state where the generated fitness score(s) indicates absence of a new optimum over one or more other fitness scores generated from one or more other iterations of the acquisition function.

17. A computer system for enhancing processing within a computing environment, the computer system comprising:
at least one processor set;
a set of one or more computer-readable storage media; and
program instructions, collectively stored in the set of one or more storage media, for causing the at least one processor set to perform computer operations comprising:
running, as part of an optimization tool, a state iteration of an acquisition function including a multi-state acquisition function engine, the optimization tool being a machine learning optimization tool to optimize, at least in part, a circuit device feature, and the multi-state acquisition function engine facilitating selecting samples for an objective function of the optimization tool, the multi-state acquisition function engine having multiple potential acquisition function states ranging from an exploitive state to an explorative state;
configuring input parameters for running a genetic algorithm engine of the optimization tool based, in part, on a current acquisition function state of the multiple potential acquisition function states of the multi-state acquisition function engine to tune the genetic algorithm engine based on the current acquisition function state;
running the genetic algorithm engine for one or more generations using the configured input parameters to generate a plurality of candidate samples for the objective function;
providing one or more selected samples of the plurality of candidate samples to the objective function for generating one or more fitness score(s) for the selected sample(s) in optimizing, at least in part, the circuit device feature; and
selecting, based at least in part on the generated fitness score(s) for the selected sample(s), a new acquisition function state of the multi-state acquisition function engine of the acquisition function for a next iteration.

18. The computer system of claim 17, wherein the computer operations further comprise data analyzing the plurality of candidate samples to select, based at least in part on the current acquisition function state, the selected sample(s) for evaluation by the objective function from the plurality of candidate samples.

19. The computer system of claim 17, wherein the multi-state acquisition function engine is a dynamic meta-heuristic engine which facilitates, in part, configuring the input parameters for running the genetic algorithm engine based on a current performance of the optimization tool.

20. The computer system of claim 17, wherein each acquisition function state of the multiple acquisition function states includes respective parameters that: weigh genetic algorithm operations that affect mutations and cloning, select an initial candidate population to prime the genetic algorithm's search, set the acquisition function's utility metric to be more exploitive or explorative, sort the plurality of candidate samples and facilitate selecting the selected sample(s) for the objective function.
